(19) United States
(12) Patent Application Publication
(10) Pub. No.: US 2025/0267982 A1
(43) Pub. Date: Aug. 21, 2025

(54) VERTICAL LIGHT-EMITTING DIODE PACKAGE STRUCTURE AND MANUFACTURING METHOD THEREOF

(71) Applicant: INGENTEC CORPORATION, Miaoli County (TW)

(72) Inventors: Hsiao-Lu CHEN, Miaoli County (TW); Ai-Sen LIU, Miaoli County (TW); Hsiang-An FENG, Miaoli County (TW); Cheng-Yu CHUNG, Miaoli County (TW)

(21) Appl. No.: 18/963,588

(22) Filed: Nov. 28, 2024

(30) Foreign Application Priority Data
Feb. 20, 2024 (TW) 113105879

(51) Int. Cl. H10H 20/813; H10H 20/01; H10H 20/831

(52) U.S. Cl. CPC H10H 20/8131; H10H 20/032; H10H 20/0364; H10H 20/831

(57) ABSTRACT

A vertical light-emitting diode package structure includes a first structural layer, a second structural layer and a third structural layer. The second structural layer is connected to the first structural layer. The third structural layer is connected to the second structural layer to make the second structural layer be arranged between the first structural layer and the third structural layer. The first structural layer includes a first substrate and a first light-emitting element. The second structural layer includes a second substrate and a second light-emitting element. The third structural layer includes a third substrate and a third light-emitting element. The first light-emitting element, the second light-emitting element and the third light-emitting element are respectively disposed on the upper surfaces of the first substrate, the second substrate and the third substrate.

### RELATED APPLICATIONS

This application claims priority to Taiwan Application Serial Number 113105879, filed Feb. 20, 2024, which is herein incorporated by reference.

### BACKGROUND

### Technical Field

The present disclosure relates to a light-emitting diode package structure. More particularly, the present disclosure relates to a vertical light-emitting diode package structure and a manufacturing method thereof which can enhance the convenience of manufacturing and reduce the size thereof.

### Description of Related Art

The conventional light-emitting diode package structure includes light-emitting diodes and a dummy plug fixed on a substrate. After the light-emitting diodes and the dummy plug are electrically connected, it is packaged with glue. However, in the conventional package structure, the light-emitting diodes are arranged horizontally. That is, the light-emitting diodes of different colors must be arranged separately in a horizontal direction, which causes the package structure to be too large, and it is difficult to achieve compactness.

### SUMMARY

According to an aspect of the present disclosure, a vertical light-emitting diode package structure includes a first structural layer, a second structural layer and a third structural layer. The first structural layer includes a first substrate, four first conductive elements, a first light-emitting element and a first dummy plug. The first substrate has an upper surface and a bottom surface opposite to the upper surface. The four first conductive elements are respectively extending from the upper surface to the bottom surface of the first substrate. The first light-emitting element is disposed on and electrically connected to an end surface of one of the four first conductive elements located on the upper surface of the first substrate. The first dummy plug is disposed on and electrically connected to an end surface of another one of the four first conductive elements located on the upper surface of the first substrate. The second structural layer is connected to the first structural layer, and the second structural layer includes a second substrate, three second conductive elements, a second light-emitting element and a second dummy plug. The second substrate has an upper surface and a bottom surface opposite to the upper surface. The three second conductive elements are respectively extending from the upper surface to the bottom surface of the second substrate, wherein the three second conductive elements are respectively electrically connected to three of the four first conductive elements which are free from connecting to the first light-emitting element. The second light-emitting element is disposed on and electrically connected to an end surface of one of the three second conductive elements located on the upper surface of the second substrate. The second dummy plug is disposed on and electrically connected to an end surface of another one of the three second conductive elements located on the upper surface of the second substrate. The third structural layer is connected to the second structural layer to make the second structural layer be arranged between the first structural layer and the third structural layer, and the third structural layer includes a third substrate, two third conductive elements, a third light-emitting element and a third dummy plug. The third substrate has an upper surface and a bottom surface opposite to the upper surface. The two third conductive elements are respectively extending from the upper surface to the bottom surface of the third substrate, wherein the two third conductive elements are respectively electrically connected to two of the three second conductive elements which are free from connecting to the second light-emitting element. The third light-emitting element is disposed on and electrically connected to an end surface of one of the two third conductive elements located on the upper surface of the third substrate. The third dummy plug is disposed on and electrically connected to an end surface of another one of the two third conductive elements located on the upper surface of the third substrate.

According to another aspect of the present disclosure, a manufacturing method of a vertical light-emitting diode package structure includes the steps as outlined below. A first-conductive-element arranging step is performed to make four first conductive elements respectively extend from an upper surface to a bottom surface of a first substrate. A first arranging step is performed to make a first light-emitting element and a first dummy plug be respectively arranged on end surfaces of two of the four first conductive elements located on the upper surface of the first substrate, and be respectively electrically connected to the two of the four first conductive elements so as to obtain a first structural layer. A second-conductive-element arranging step is performed to make three second conductive elements respectively extend from an upper surface to a bottom surface of a second substrate. A second arranging step is performed to make a second light-emitting element and a second dummy plug be respectively arranged on end surfaces of two of the three second conductive elements located on the upper surface of the second substrate, and be respectively electrically connected to the two of the three second conductive elements so as to obtain a second structural layer. A third-conductive-element arranging step is performed to make two third conductive elements respectively extend from an upper surface to a bottom surface of a third substrate. A third arranging step is performed to make a third light-emitting element and a third dummy plug be respectively arranged on end surfaces of the two third conductive elements located on the upper surface of the third substrate, and be respectively electrically connected to the two third conductive elements so as to obtain a third structural layer. An assembling step is performed to make the first structural layer, the second structural layer and the third structural layer be sequentially stacked and connected, make the three second conductive elements be respectively electrically connected to three of the four first conductive elements which are free from connecting to the first light-emitting element, and make the two third conductive elements be respectively electrically connected to two of the three second conductive elements which are free from connecting to the second light-emitting element so as to form a vertical light-emitting diode package structure.

### BRIEF DESCRIPTION OF THE DRAWINGS

The present disclosure can be more fully understood by reading the following detailed description of the embodiment, with reference made to the accompanying drawings as follows:

FIG. 1A is a three-dimensional schematic view of a vertical light-emitting diode package structure according to an embodiment of the present disclosure.

FIG. 1B is an exploded schematic view of the vertical light-emitting diode package structure in FIG. 1A.

FIG. 2A is a cross-sectional schematic view of the vertical light-emitting diode package structure in FIG. 1A along Line 2A-2A.

FIG. 2B is a cross-sectional schematic view of the vertical light-emitting diode package structure in FIG. 1A along Line 2B-2B.

FIG. 3 is a three-dimensional schematic view of a vertical light-emitting diode package structure according to another embodiment of the present disclosure.

FIG. 4A is a bottom schematic view of the first substrate in FIG. 3.

FIG. 4B is a bottom schematic view of the second substrate in FIG. 3.

FIG. 4C is a bottom schematic view of the third substrate in FIG. 3.

FIG. 5 is a step flow chart of a manufacturing method of a vertical light-emitting diode package structure according to one another embodiment of the present disclosure.

FIG. 6A to FIG. 6H are respectively cross-sectional schematic views of each steps in the manufacturing method of the vertical light-emitting diode package structure.

FIG. 7A to FIG. 7D are respectively other cross-sectional schematic views of each steps in the manufacturing method of the vertical light-emitting diode package structure.

### DETAILED DESCRIPTION

The present disclosure will be further exemplified by the following specific embodiments. However, the embodiments can be applied to various inventive concepts and can be embodied in various specific ranges. The specific embodiments are only for the purposes of description, and are not limited to these practical details thereof.

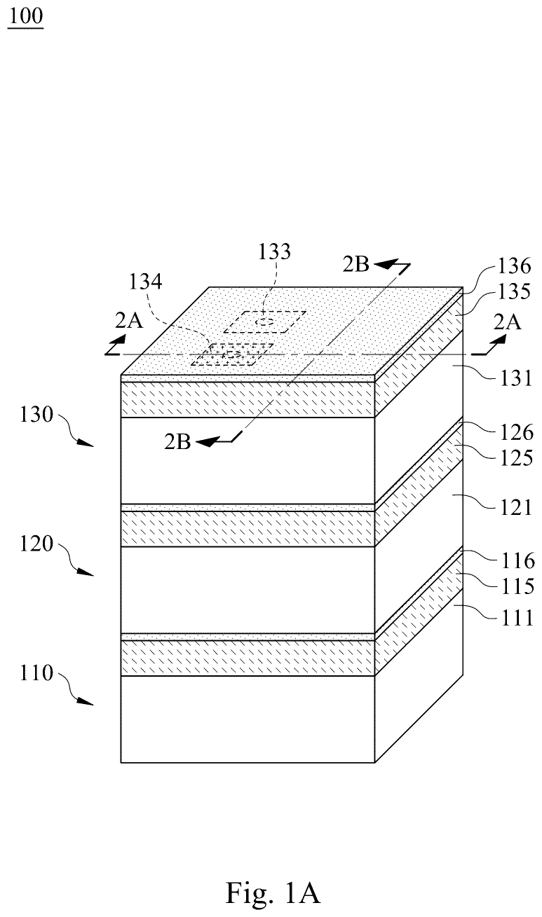

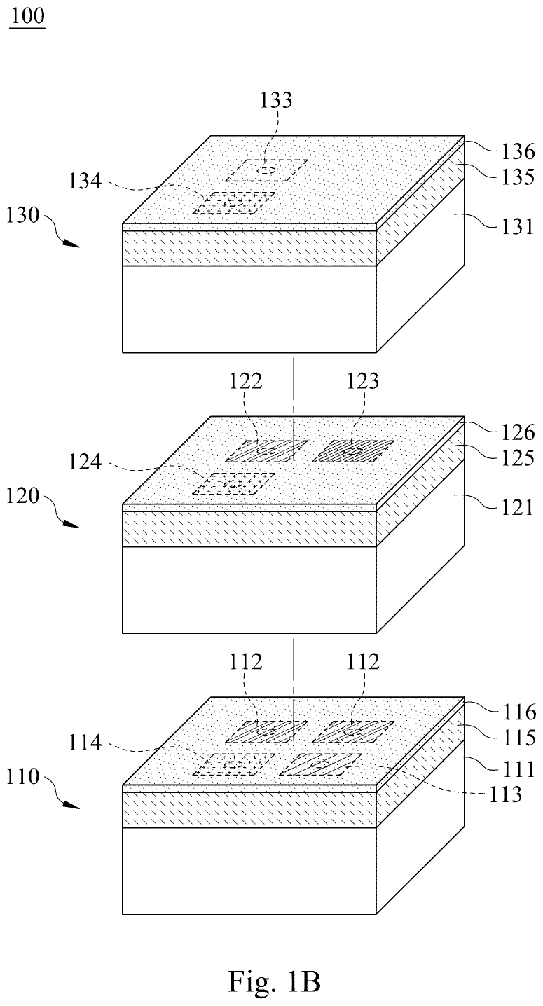

Please refer to FIG. 1A and FIG. 1B. FIG. 1A is a three-dimensional schematic view of a vertical light-emitting diode package structure 100 according to an embodiment of the present disclosure. FIG. 1B is an exploded schematic view of the vertical light-emitting diode package structure 100 in FIG. 1A. The vertical light-emitting diode package structure 100 includes a first structural layer 110, a second structural layer 120 and a third structural layer 130. The second structural layer 120 is connected to the first structural layer 110. The third structural layer 130 is connected to the second structural layer 120 and make the second structural layer 120 be arranged between the first structural layer 110 and the third structural layer 130.

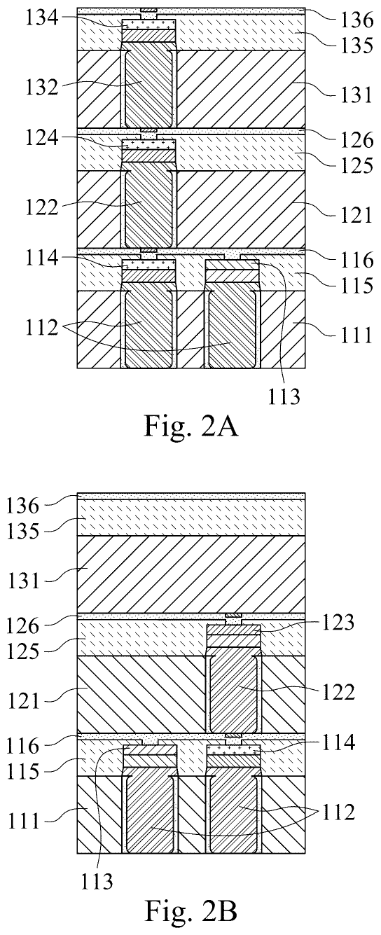

Please refer to FIG. 2A and FIG. 2B. FIG. 2A is a cross-sectional schematic view of the vertical light-emitting diode package structure 100 in FIG. 1A along Line 2A-2A. FIG. 2B is a cross-sectional schematic view of the vertical light-emitting diode package structure 100 in FIG. 1A along Line 2B-2B. The first structural layer 110 includes a first substrate 111, four first conductive elements 112, a first light-emitting element 113 and a first dummy plug 114. The first substrate 111 has an upper surface and a bottom surface opposite to the upper surface. The four first conductive elements 112 respectively extend from the upper surface to the bottom surface of the first substrate 111 so as to make the elements on both sides of the first substrate 111 be electrically connected.

The first light-emitting element 113 is disposed on and electrically connected to an end surface of one of the four first conductive elements 112 located on the upper surface of the first substrate 111. The first dummy plug 114 is disposed on and electrically connected to an end surface of another one of the four first conductive elements 112 located on the upper surface of the first substrate 111. The first light-emitting element 113 and the first dummy plug 114 can be fixed on the first conductive elements 112 through conductive glue so as to achieve the structural connection and electrical connection simultaneously, and the overall size of the first structural layer 110 can be reduced.

The second structural layer 120 includes a second substrate 121, three second conductive elements 122, a second light-emitting element 123 and a second dummy plug 124. The second substrate 121 has an upper surface and a bottom surface opposite to the upper surface, and the second substrate 121 can have great light transmittance. The three second conductive elements 122 respectively extend from the upper surface to the bottom surface of the second substrate 121. The second light-emitting element 123 is disposed on and electrically connected to an end surface of one of the three second conductive elements 122 located on the upper surface of the second substrate 121. The second dummy plug 124 is disposed on and electrically connected to an end surface of another one of the three second conductive elements 122 located on the upper surface of the second substrate 121. The structure and arrangement of elements in the second structural layer 120 is the same as or similar to the aforementioned first structural layer 110, and the details thereof will not be given again herein.

The three second conductive elements 122 are respectively electrically connected to three of the four first conductive elements 112 which are free from connecting to the first light-emitting element 113. In detail, the three second conductive elements 122 can be electrically connected to the first conductive elements 112 through end surfaces thereof located on the bottom surface of the second substrate 121. Furthermore, the three second conductive elements 122 can further be directly in contact with end surfaces of the first conductive elements 112 located on the upper surface of the first substrate 111 or with the first dummy plug 114 through the end surfaces of the three second conductive elements 122 located on the bottom surface of the second substrate 121, and be connected through conductive glue so as to achieve the structural connection and electrical connection simultaneously.

The third structural layer 130 includes a third substrate 131, two third conductive elements 132, a third light-emitting element 133 and a third dummy plug 134. The third substrate 131 has an upper surface and a bottom surface opposite to the upper surface, and the third substrate 131 can have great light transmittance. The two third conductive elements 132 respectively extend from the upper surface to the bottom surface of the third substrate 131, and are respectively electrically connected to two of the three second conductive elements 122 which are free from connecting to the second light-emitting element 123. The third light-emitting element 133 is disposed on and electrically connected to an end surface of one of the two third conductive elements 132 located on the upper surface of the third substrate 131. The third dummy plug 134 is disposed on and electrically connected to an end surface of another one of the two third conductive elements 132 located on the upper surface of the third substrate 131. The structure and arrangement of elements in the third structural layer 130 is the same as or similar to the aforementioned first structural layer 110 and the aforementioned second structural layer 120, and the details thereof will not be given again herein.

It should be mentioned that, the three second conductive elements 122 can be respectively aligned with the three of the four first conductive elements 112 which are free from connecting to the first light-emitting element 113. The two third conductive elements 132 can be respectively aligned with the two of the three second conductive elements 122 which are free from connecting to the second light-emitting element 123, and the four first conductive elements 112 can be arranged in an array of 2×2. Therefore, it is favorable for reducing the difficulty of structural arrangement, and also reducing the distance between elements. Also, the first light-emitting element 113, the second light-emitting element 123 and the third light-emitting element 133 can independently emit light without interfering each other.

Moreover, the first light-emitting element 113 can be a red light-emitting element, the second light-emitting element 123 can be a green light-emitting element, and the third light-emitting element 133 can be a blue light-emitting element. In contrast, an area of the first light-emitting element 113 can be larger than an area of the second light-emitting element 123, and the area of the second light-emitting element 123 can be larger than an area of the third light-emitting element 133. Therefore, the light emitted from the first light-emitting element 113 and the second light-emitting element 123 can be increased, which is favorable for mixing the color light of the vertical light-emitting diode package structure 100.

The vertical light-emitting diode package structure 100 can further include two glue layers 115, 125, which can be respectively arranged between the first structural layer 110 and the second structural layer 120 and between the second structural layer 120 and the third structural layer 130. The two glue layers 115, 125 can provide the protective effect so as to enhance the service life of the vertical light-emitting diode package structure 100. The vertical light-emitting diode package structure 100 can further include a glue layer 135. The glue layer 135 can be arranged on the upper surface of the third substrate 131 so as to cover the third light-emitting element 133 and the third dummy plug 134.

The vertical light-emitting diode package structure 100 can further include two conductive layers 116, 126, which can be respectively arranged between the first structural layer 110 and the second structural layer 120 and between the second structural layer 120 and the third structural layer 130. The first structural layer 110, the second structural layer 120 and the third structural layer 130 can be electrically connected through the two conductive layers 116, 126. It is free from wire bonding to build the circuit, and the size thereof is reduced and the manufacturing effect and yield are enhanced. The vertical light-emitting diode package structure 100 can further include a conductive layer 136. The conductive layer 136 can be arranged on the upper surface of the glue layer 135 for the vertical light-emitting diode package structure 100 to be electrically connected to the outside.

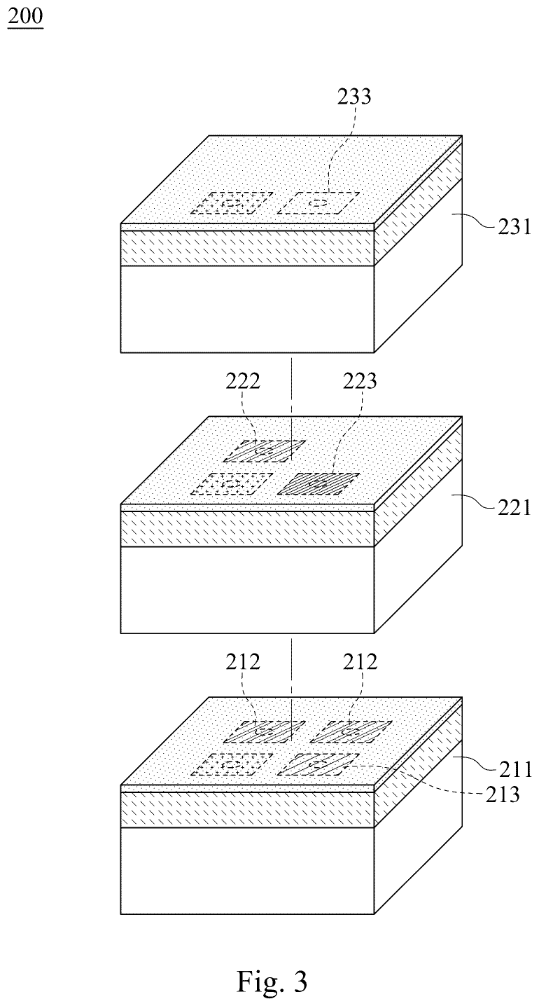

Please refer to FIG. 3. FIG. 3 is a three-dimensional schematic view of a vertical light-emitting diode package structure 200 according to another embodiment of the present disclosure. The vertical light-emitting diode package structure 200 is similar to the aforementioned vertical light-emitting diode package structure 100. The difference is, the three second conductive elements 222 can be respectively aligned with three of the four first conductive elements 212, the two third conductive elements 232 can be respectively aligned with two of the three second conductive elements 222, the first light-emitting element 213, the second light-emitting element 223 and the third light-emitting element 233 can be aligned, and the four first conductive elements 212 can be arranged in an array of 2×2. By aligning the first light-emitting element 213, the second light-emitting element 223 and the third light-emitting element 233, the spatial mixing effect of color light can be achieved so as to enhance the application scope of the vertical light-emitting diode package structure 200.

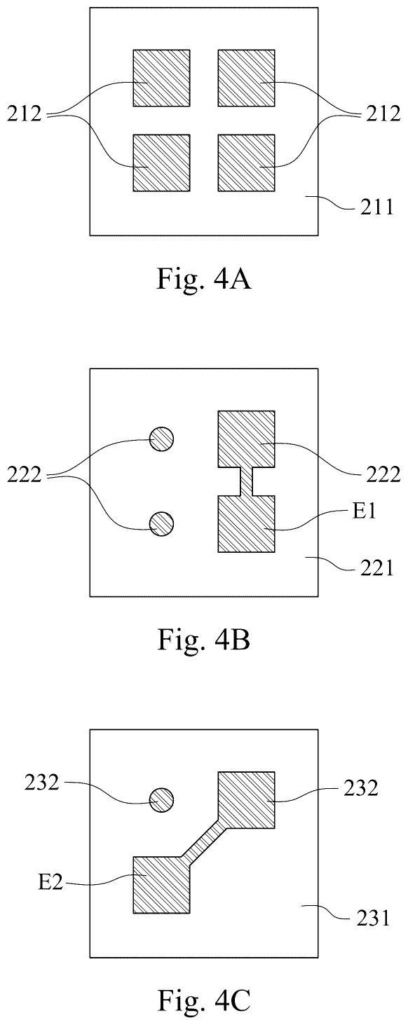

Please refer to FIG. 4A, FIG. 4B and FIG. 4C. FIG. 4A is a bottom schematic view of the first substrate 211 in FIG. 3. FIG. 4B is a bottom schematic view of the second substrate 221 in FIG. 3. FIG. 4C is a bottom schematic view of the third substrate 231 in FIG. 3. Because the first light-emitting element 213, the second light-emitting element 223 and the third light-emitting element 233 are aligned, the circuits of the three second conductive elements 222 and the two third conductive elements 232 should be respectively arranged on the bottom surfaces of the second substrate 221 and the third substrate 231 so as to ensure the circuit is correctly built. In FIG. 3 and FIG. 4B, the second conductive element 222 in the upper right corner is blocked by the first light-emitting element 213, and it needs a conductive extending element E1 to be electrically connected to the first conductive element 212. Similarly, in FIG. 3 and FIG. 4C, the third conductive element 232 in the upper right corner is blocked by the second light-emitting element 223, and it needs a conductive extending element E2 to be electrically connected to the three second conductive elements 222.

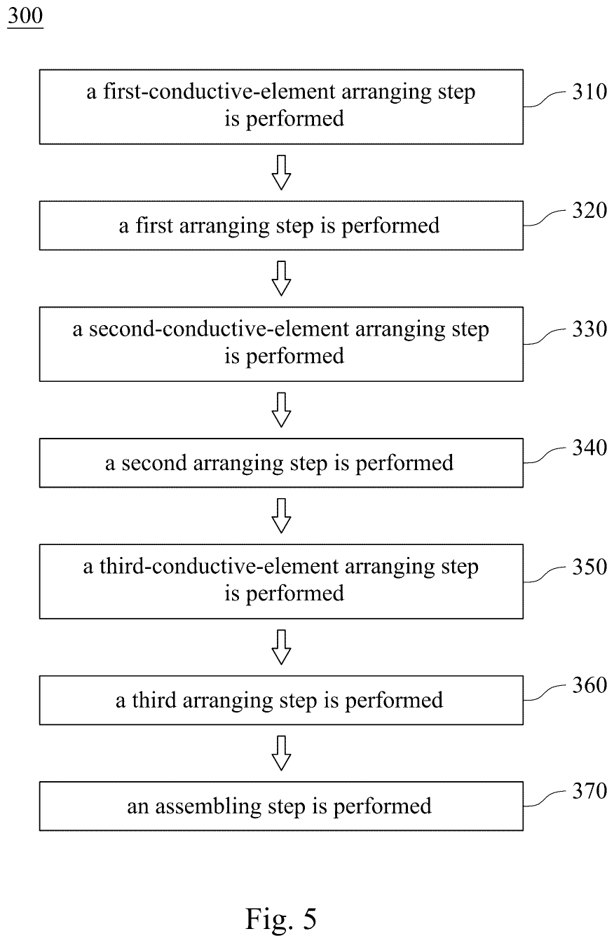

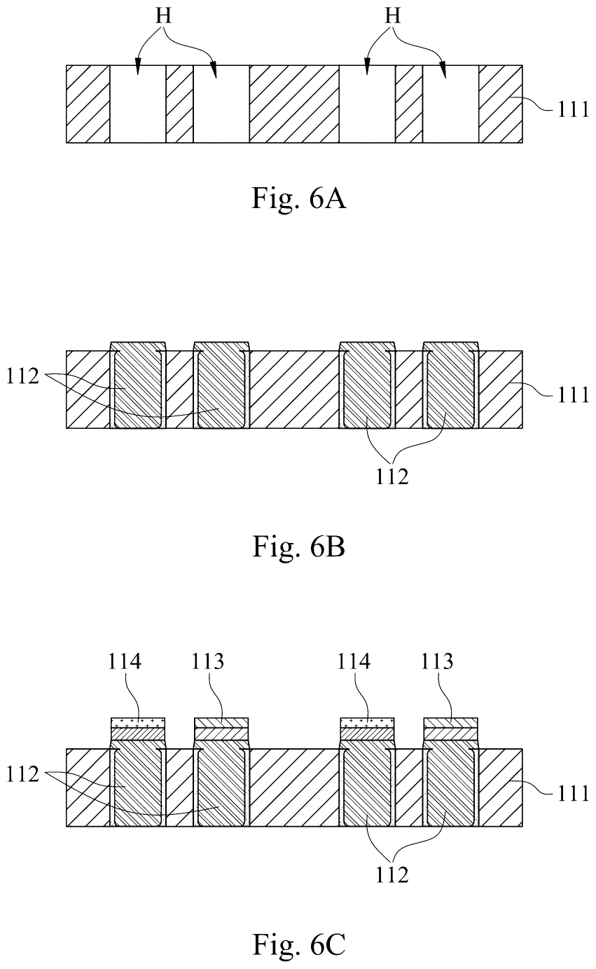

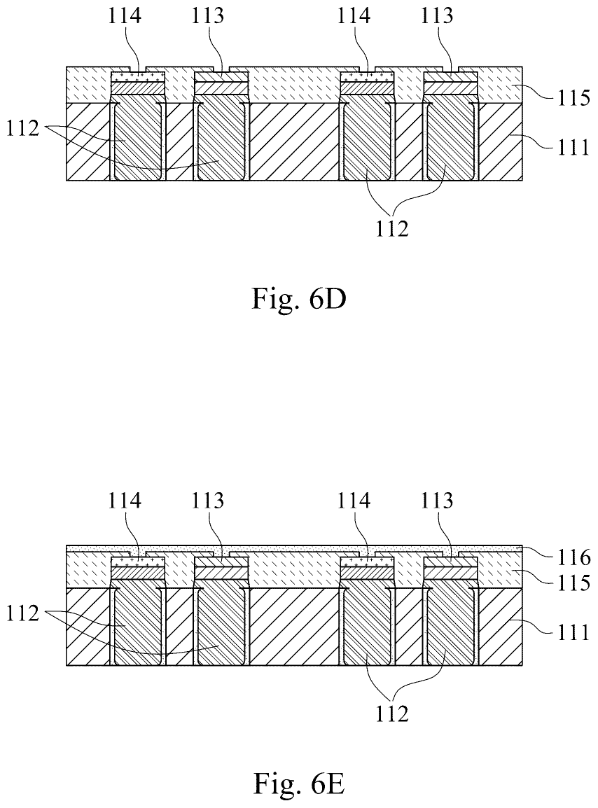

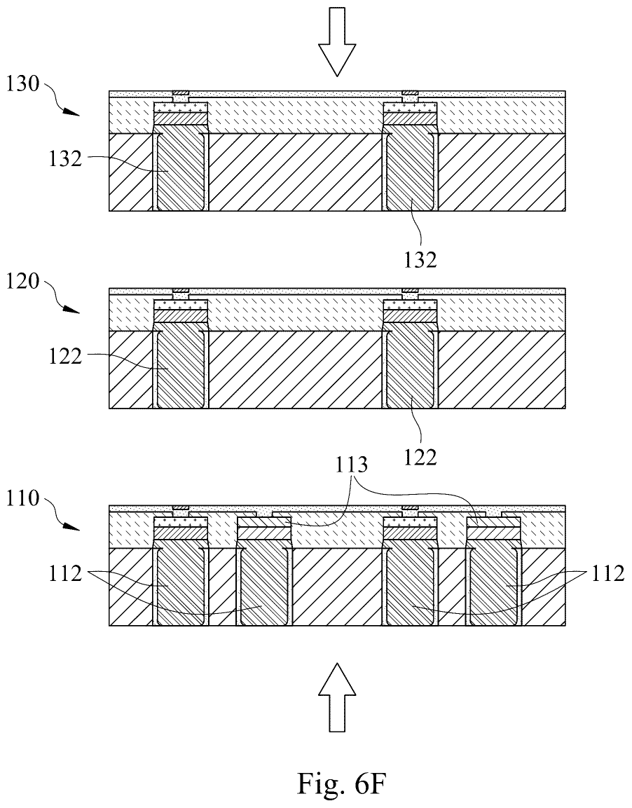

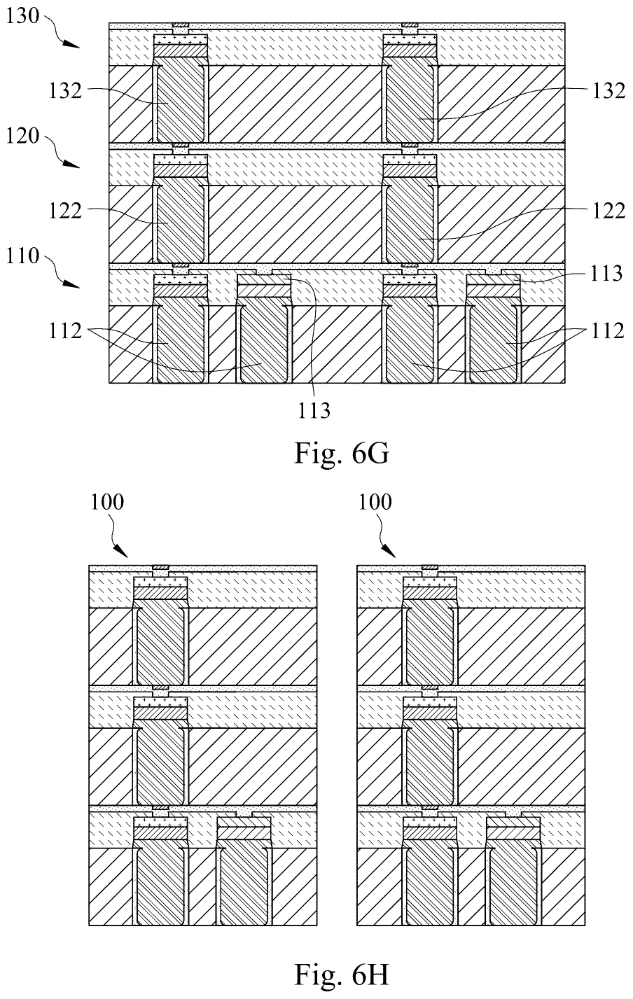

Please refer to FIG. 5, FIG. 6A, FIG. 6B, FIG. 6C, FIG. 6D, FIG. 6E, FIG. 6F, FIG. 6G and FIG. 6H. FIG. 5 is a step flow chart of a manufacturing method of a vertical light-emitting diode package structure 300 according to one another embodiment of the present disclosure. FIG. 6A to FIG. 6H are respectively cross-sectional schematic views of each steps in the manufacturing method of the vertical light-emitting diode package structure 300. The manufacturing method of the vertical light-emitting diode package structure 300 includes Step 310, Step 320, Step 330, Step 340, Step 350, Step 360 and Step 370.

In Step 310, a first-conductive-element arranging step is performed to make the four first conductive elements 112 respectively extend from the upper surface to the bottom surface of the first substrate 111. Please refer to FIG. 6A. Take the first substrate 111 for example herein, the first substrate 111 can be a through glass via (TGV) substrate, which can have great light transmittance and include through holes H for arranging other elements. The number and position of the through holes H can be adjusted according to the requirement, and the present disclosure is not limited thereto. Please refer to FIG. 6B. The four first conductive elements 112 can be copper columns, so it is free from etching and the manufacturing cost can be reduced. The four first conductive elements 112 can have head portions whose widths are larger than diameters of the through holes H. A glue can fill between the four first conductive elements 112 and the through holes H and between the head portions and the upper surface of the first substrate 111 so as to obtain the effect of fixing the four first conductive elements 112.

Please refer to FIG. 6C. In Step 320, a first arranging step is performed to make the first light-emitting element 113 and the first dummy plug 114 be respectively arranged on the end surfaces of the two of the four first conductive elements 112 located on the upper surface of the first substrate 111, and be respectively electrically connected to the aforementioned two first conductive elements 112 so as to obtain the first structural layer 110. Please refer to FIG. 6D and FIG. 6E. When the first light-emitting element 113 and the first dummy plug 114 are arranged, the glue layer 115 can be arranged to cover the upper surface of the first substrate 111, the first light-emitting element 113 and the first dummy plug 114. Then, laser drilling is performed and the conductive layer 116 is arranged.

In Step 330, a second-conductive-element arranging step is performed to make the three second conductive elements 122 respectively extend from the upper surface to the bottom surface of the second substrate 121. In Step 340, a second arranging step is performed to make the second light-emitting element 123 and the second dummy plug 124 be respectively arranged on the end surfaces of the two of the three second conductive elements 122 located on the upper surface of the second substrate 121, and be respectively electrically connected to the two second conductive elements 122 so as to obtain the second structural layer 120. The details of Step 330 and Step 340 are respectively the same as or similar to Step 310 and Step 320, and the details thereof will not be given again herein.

In Step 350, a third-conductive-element arranging step is performed to make the two third conductive elements 132 respectively extend from the upper surface to the bottom surface of the third substrate 131. In Step 360, a third arranging step is performed to make the third light-emitting element 133 and the third dummy plug 134 be respectively arranged on the end surfaces of the two third conductive elements 132 located on the upper surface of the third substrate 131, and be respectively electrically connected to the two third conductive elements 132 so as to obtain the third structural layer 130. The details of Step 350 and Step 360 are respectively the same as or similar to Step 310 and Step 320, and the details thereof will not be given again herein.

In Step 370, an assembling step is performed to make the first structural layer 110, the second structural layer 120 and the third structural layer 130 be sequentially stacked and connected, make the three second conductive elements 122 be respectively electrically connected to the three of the four first conductive elements 112 which are free from connecting to the first light-emitting element 113, and make the two third conductive elements 132 be respectively electrically connected to the two of the three second conductive elements 122 which are free from connecting to the second light-emitting element 123 so as to form the vertical light-emitting diode package structure 100. Please refer to FIG. 6F to FIG. 6H. In detail, a conductive glue can be first applied to the positions of the first structural layer 110, the second structural layer 120 and the third structural layer 130 to be electrically connected. Then, the first structural layer 110, the second structural layer 120 and the third structural layer 130 are aligned, stacked and compressed, and then cut to obtain the plurality of vertical light-emitting diode package structures 100.

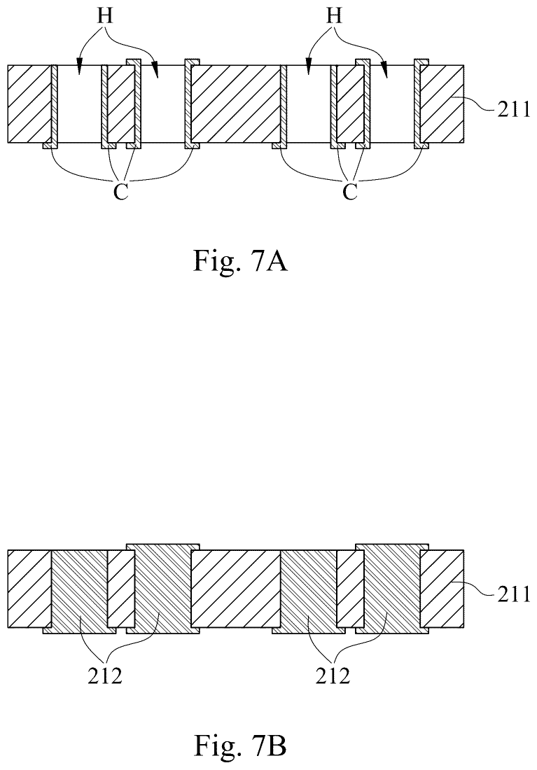

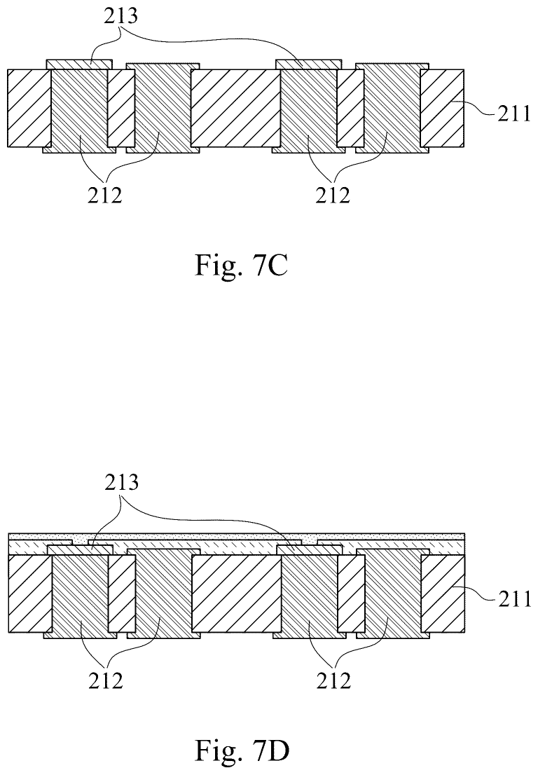

Please refer to FIG. 7A, FIG. 7B, FIG. 7C and FIG. 7D. FIG. 7A to FIG. 7D are respectively another cross-sectional schematic views of each steps in the manufacturing method of the vertical light-emitting diode package structure 300. In FIG. 7A to FIG. 7D, the four first conductive elements 212, the three second conductive elements 222 and the two third conductive elements 232 are manufactured by the chemical plating method. For example, a seed layer C can be first sputtered in the through holes H of the first substrate 211, and then the through holes H are filled by the chemical plating method so as to form the four first conductive elements 212, the three second conductive elements 222 and the two third conductive elements 232. In FIG. 7D, the thickness can be reduced by the chemical plating method, and the package size can be further reduced. Moreover, it is free from filling the glue to fix, so the complexity of manufacturing can be reduced.

In this regard, the first light-emitting element, the second light-emitting element and the third light-emitting element are stacked in a vertical direction in the vertical light-emitting diode package structure of the present disclosure, the structural size after packaging can be effectively reduced. Furthermore, by adopting independent packaging and modular design, the manufacturing process of die bonding can be simplified, and the difficulty of testing and repairing can be reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A vertical light-emitting diode package structure, comprising:
a first structural layer, comprising:
a first substrate having an upper surface and a bottom surface opposite to the upper surface;
four first conductive elements, respectively extending from the upper surface to the bottom surface of the first substrate;
a first light-emitting element, disposed on and electrically connected to an end surface of one of the four first conductive elements located on the upper surface of the first substrate; and
a first dummy plug, disposed on and electrically connected to an end surface of another one of the four first conductive elements located on the upper surface of the first substrate;
a second structural layer, connected to the first structural layer, and the second structural layer comprising:
a second substrate having an upper surface and a bottom surface opposite to the upper surface;
three second conductive elements, respectively extending from the upper surface to the bottom surface of the second substrate, wherein the three second conductive elements are respectively electrically connected to three of the four first conductive elements which are free from connecting to the first light-emitting element;
a second light-emitting element, disposed on and electrically connected to an end surface of one of the three second conductive elements located on the upper surface of the second substrate; and
a second dummy plug, disposed on and electrically connected to an end surface of another one of the three second conductive elements located on the upper surface of the second substrate; and
a third structural layer, connected to the second structural layer to make the second structural layer be arranged between the first structural layer and the third structural layer, and the third structural layer comprising:
a third substrate having an upper surface and a bottom surface opposite to the upper surface;
two third conductive elements, respectively extending from the upper surface to the bottom surface of the third substrate, wherein the two third conductive elements are respectively electrically connected to two of the three second conductive elements which are free from connecting to the second light-emitting element;
a third light-emitting element, disposed on and electrically connected to an end surface of one of the two third conductive elements located on the upper surface of the third substrate; and
a third dummy plug, disposed on and electrically connected to an end surface of another one of the two third conductive elements located on the upper surface of the third substrate.

2. The vertical light-emitting diode package structure of claim 1, wherein the three second conductive elements are respectively aligned with the three of the four first conductive elements which are free from connecting to the first light-emitting element, and the two third conductive elements are respectively aligned with the two of the three second conductive elements which are free from connecting to the second light-emitting element.

3. The vertical light-emitting diode package structure of claim 2, wherein the four first conductive elements are arranged in an array of 2×2.

4. The vertical light-emitting diode package structure of claim 1, wherein the three second conductive elements are respectively aligned with three of the four first conductive elements, the two third conductive elements are respectively aligned with two of the three second conductive elements, and the first light-emitting element, the second light-emitting element and the third light-emitting element are aligned.

5. The vertical light-emitting diode package structure of claim 4, wherein the four first conductive elements are arranged in an array of 2×2.

6. The vertical light-emitting diode package structure of claim 1, wherein the first light-emitting element is a red light-emitting element, the second light-emitting element is a green light-emitting element, and the third light-emitting element is a blue light-emitting element.

7. A manufacturing method of a vertical light-emitting diode package structure, comprising:
performing a first-conductive-element arranging step to make four first conductive elements respectively extend from an upper surface to a bottom surface of a first substrate;
performing a first arranging step to make a first light-emitting element and a first dummy plug be respectively arranged on end surfaces of two of the four first conductive elements located on the upper surface of the first substrate, and be respectively electrically connected to the two of the four first conductive elements so as to obtain a first structural layer;
performing a second-conductive-element arranging step to make three second conductive elements respectively extend from an upper surface to a bottom surface of a second substrate;
performing a second arranging step to make a second light-emitting element and a second dummy plug be respectively arranged on end surfaces of two of the three second conductive elements located on the upper surface of the second substrate, and be respectively electrically connected to the two of the three second conductive elements so as to obtain a second structural layer;
performing a third-conductive-element arranging step to make two third conductive elements respectively extend from an upper surface to a bottom surface of a third substrate;
performing a third arranging step to make a third light-emitting element and a third dummy plug be respectively arranged on end surfaces of the two third conductive elements located on the upper surface of the third substrate, and be respectively electrically connected to the two third conductive elements so as to obtain a third structural layer; and
performing an assembling step to make the first structural layer, the second structural layer and the third structural layer be sequentially stacked and connected, make the three second conductive elements be respectively electrically connected to three of the four first conductive elements which are free from connecting to the first light-emitting element, and make the two third conductive elements be respectively electrically connected to two of the three second conductive elements which are free from connecting to the second light-emitting element so as to form a vertical light-emitting diode package structure.

8. The manufacturing method of the vertical light-emitting diode package structure of claim 7, wherein the three second conductive elements are respectively aligned with the three of the four first conductive elements which are free from connecting to the first light-emitting element, and the two third conductive elements are respectively aligned with the two of the three second conductive elements which are free from connecting to the second light-emitting element.

9. The manufacturing method of the vertical light-emitting diode package structure of claim 8, wherein the four first conductive elements are arranged in an array of 2×2.

10. The manufacturing method of the vertical light-emitting diode package structure of claim 7, wherein the three second conductive elements are respectively aligned with three of the four first conductive elements, the two third conductive elements are respectively aligned with two of the three second conductive elements, and the first light-emitting element, the second light-emitting element and the third light-emitting element are aligned.

11. The manufacturing method of the vertical light-emitting diode package structure of claim 10, wherein the four first conductive elements are arranged in an array of 2×2.

12. The manufacturing method of the vertical light-emitting diode package structure of claim 7, wherein the first light-emitting element is a red light-emitting element, the second light-emitting element is a green light-emitting element, and the third light-emitting element is a blue light-emitting element.
